(19) United States
(12) Patent Application Publication
(10) Pub. No.: US 2015/0187853 A1
(43) Pub. Date: Jul. 2, 2015

(54) DISPLAY DEVICE AND MANUFACTURING METHOD THEREOF

(71) Applicant: SAMSUNG DISPLAY CO., LTD., Yongin-City (KR)

(72) Inventors: Guang-Hai JIN, Seoul (KR); In-Young JUNG, Goyang-si (KR); Jae-Beom CHOI, Suwon-si (KR)

(21) Appl. No.: 14/527,985

(22) Filed: Oct. 30, 2014

(30) Foreign Application Priority Data
Dec. 30, 2013 (KR) 10-2013-0167293

(51) Int. Cl. H01L 27/32; H01L 29/786; H01L 51/56

(52) U.S. Cl. CPC H01L 27/3262; H01L 51/56; H01L 29/78675; H01L 29/78645; H01L 29/78609; H01L 2227/323

(57) ABSTRACT

A display device includes an organic light emitting element and a capacitor connected to the a thin film transistor. The transistor includes a semiconductor layer uniformly disposed on an entire area of a substrate. The transistor also includes a first insulating layer on the semiconductor layer, a gate electrode pattern on the first insulating layer, a gate guard on a same layer as and surrounding the gate electrode pattern, a second insulating layer on the gate electrode pattern and the gate guard, and source and drain electrodes passing through the first insulating layer and the second insulating layer and connected to the semiconductor layer. The gate electrode pattern includes a plurality of gate center portions and a gate peripheral portion having a closed-loop shape extending from the gate center portions.

### CROSS-REFERENCE TO RELATED APPLICATION

Korean Patent Application No. 10-2013-0167293, filed on Dec. 30, 2013, and entitled, “Display Device and Manufacturing Method Thereof,” is incorporated by reference herein in its entirety.

### BACKGROUND

1. Field

One or more embodiments described herein relate to a display device and a method of manufacturing a display device.

2. Description of the Related Art

A display includes a plurality of pixels in an area defined by a black matrix or a pixel define layer. Examples of displays include liquid crystal displays, organic light emitting displays, plasma display panels, and electrophoretic displays. These displays differ in terms of their methods of light emission.

Organic light emitting displays emit light based on a combination of electrons and holes in a layer including an organic material. Displays of this type may be categorized as passive matrix displays and an active matrix displays. Active matrix displays include a switching element (e.g., thin film transistor) in each pixel for controlling light emission.

In one type of active matrix display, each pixel includes an organic light emitting diode formed on a substrate. The substrate is patterned for a thin film transistor, a capacitor, and associated wirings. In order to form a micro pattern including the thin film transistor on the substrate, the pattern is transferred to an array substrate using a mask having the micro pattern formed thereon. This approach of using a mask along with a patterning process increases the cost and complexity of manufacturing the display. A display manufactured in this way may also have diminished display quality, for example, as a result of an increase in leakage current and/or other effects.

### SUMMARY

In accordance with one embodiment, a display device includes a substrate; a thin film transistor including a semiconductor layer on the substrate; and an organic light emitting element and a capacitor electrically connected to the thin film transistor, wherein the semiconductor layer is uniformly disposed on an entire area of the substrate. The thin film transistor includes a first insulating layer on the semiconductor layer; a gate electrode pattern on the first insulating layer and including a plurality of gate center portions and a gate peripheral portion having a closed-loop shape extending from the gate center portions; a gate guard on a same layer as and surrounding the gate electrode pattern; a second insulating layer on the gate electrode pattern and the gate guard; and a source electrode and a drain electrode passing through the first insulating layer and the second insulating layer and connected to the semiconductor layer.

The gate guard may include a same material as the gate electrode pattern. The source electrode and the drain electrode may be connected to the semiconductor layer through empty spaces of the closed loop formed by the gate center portions and the gate peripheral portions.

In accordance with another embodiment, a method of manufacturing a display device includes uniformly forming a semiconductor layer on an entire area of a substrate which includes an organic light emitting element, a thin film transistor, and a capacitor; forming a first insulating layer on the semiconductor layer; performing a first mask process which includes patterning a conductive layer on the first insulating layer to form a gate electrode pattern having a plurality of gate center portions and a gate peripheral portion in a closed-loop shape extending from the gate center portions, a gate guard surrounding the gate electrode pattern, and a pixel electrode of the organic light emitting element and an upper electrode of the capacitor; performing a second mask process which includes patterning a second insulating layer to expose the pixel electrode, the upper electrode, and the semiconductor layer of the thin film transistor; performing a third mask process which includes patterning a conductive layer to form a source electrode and a drain electrode which contact an exposed portion of the semiconductor layer; and performing a fourth mask process which includes patterning a pixel-define-layer forming material layer to expose the pixel electrode.

The gate guard may be formed on the same layer as the gate electrode pattern and surrounds the gate electrode pattern. The gate guard may include a same material as the gate electrode pattern.

The method may include doping the semiconductor layer with impurities using the gate electrode pattern and the gate guard as masks. The thin film transistor area may expose the semiconductor layer and may include empty spaces of a closed loop formed by the gate center portions and the gate peripheral portion.

In accordance with another embodiment, a transistor includes a drain electrode; a source electrode; a semiconductor layer; and a multiple gate structure including an insulating material between a first gate area and a second gate area, wherein the drain and source electrodes are electrically connected to the semiconductor layer and wherein the semiconductor layer overlaps the first gate area and the second gate area. The transistor may include a gate region adjacent the first and second gate areas. The gate region may surround the first and second gate areas, and the drain and source electrodes may overlap the gate region. The first and second gate areas may block leakage current in a predetermined direction.

The multiple gate structure may include a third gate area between the first and second gate areas, and wherein the insulating material extends between the first and third gate areas and between the second and third gate areas.

The semiconductor layer may be continuously disposed on a substrate to overlap the transistor and at least one of additional transistor, a capacitor, or a light emitting layer. The semiconductor layer may be continuously disposed on a substrate to overlap the transistor, additional transistor, a capacitor, and a light emitting layer. The semiconductor layer may be an unpatterned layer. The transistor may include a gate guard adjacent the multiple gate structure.

In accordance with another embodiment, a pixel includes a capacitor; a light emitting layer; and a transistor between the capacitor and light emitting layer, and including: a drain electrode; a source electrode; a semiconductor layer; and a multiple gate structure including an insulating material between a first gate area and a second gate area, wherein the drain and source electrodes are electrically connected to the semiconductor layer and wherein the semiconductor layer overlaps the first gate area and the second gate area. The semiconductor layer may be continuously disposed on a substrate to overlap the capacitor and light emitting layer. The pixel may include a gate region which surrounds the first and second gate areas, wherein the drain and source electrodes overlap the gate region.

### BRIEF DESCRIPTION OF THE DRAWINGS

Features will become apparent to those of skill in the art by describing in detail exemplary embodiments with reference to the attached drawings in which:

FIG. 1 illustrates a pixel in one type of organic light emitting display device;

FIG. 2 illustrates an organic light emitting element EL, thin film transistors TFT1 and TFT2, and a storage capacitor Cst in FIG. 1;

FIG. 3 illustrates a thin film transistor in one type of organic light emitting display device;

FIG. 4 illustrates an embodiment of a pixel of an organic light emitting display;

FIG. 5 illustrates an example of an organic light emitting element EL, thin film transistors TFT1 and TFT2, and a storage capacitor Cst in FIG. 4;

FIG. 6 illustrates an embodiment of a thin film transistor;

FIG. 7 illustrates another embodiment of a thin film transistor;

FIG. 8A illustrates leakage current for one type of thin film transistor, and FIG. 8B illustrates an example of leakage current of a thin film transistor according to one embodiment;

FIGS. 9 through 16 illustrate operations included in an embodiment of a method for manufacturing an organic light emitting display device.

### DETAILED DESCRIPTION

Example embodiments are described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

When an element is referred to as being “connected” to another element, the element is “directly connected” to the other element, or “electrically connected” to the other element with one or more intervening elements interposed therebetween. It will be further understood that the terms “comprises,” “comprising,” “includes” and/or “including,” when used in this specification, specify the presence of stated features, integers, steps, operations, elements, and/or components, but do not preclude the presence or addition of one or more other features, integers, steps, operations, elements, components, and/or groups thereof.

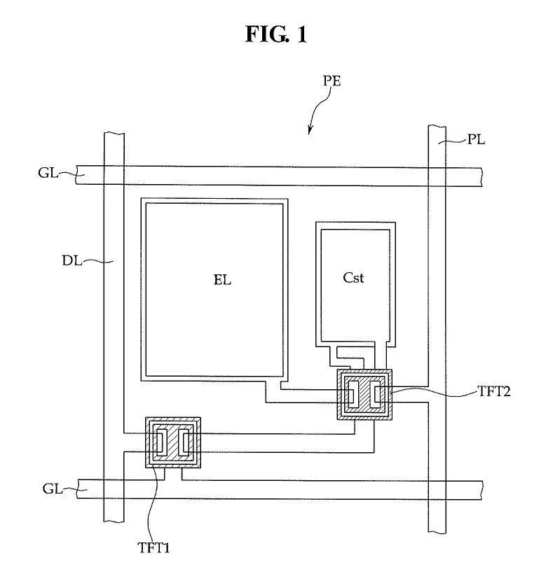

FIG. 1 illustrates a pixel in one type of organic light emitting display device which has been proposed. Referring to FIG. 1, the pixel PE includes an organic light emitting element EL, two thin film transistors TFT1 and TFT2, and a storage capacitor Cst. The pixel may therefore be said to have a 2Tr-1Cap structure. The transistors and capacitor are in a pixel area PE defined by a gate line GL and a data line DL or pixel define layers. In this device, the pixel is the smallest unit that emits light for displaying an image, and the pixel area PE refers to an area where the pixels are formed.

One of the two thin film transistors is a switching transistor TFT1 for transmitting a data signal from the data line DL in accordance with a switching signal applied from the gate line GL. The other transistor is a driving transistor TFT2 for applying a driving voltage to the organic light emitting element EL.

The switching transistor TFT1 is used as a switching element for selecting a pixel area for light emission. When the switching transistor TFT1 is turned on, charge is stored in the storage capacitor Cst. The amount of stored charge is proportional to the voltage (also called electric potential difference) applied from the data line DL.

When the switching transistor TFT1 is turned off, a gate potential of the driving transistor TFT2 is increased in accordance with the potential energy stored in the storage capacitor Cst. When the gate potential of the driving transistor TFT2 is increased above a threshold voltage, the driving transistor TFT2 is turned on. In this case, the voltage previously applied to a power line PL is applied to the organic light emitting element EL via the driving transistor TFT2. As a result, the organic light emitting element EL emits light.

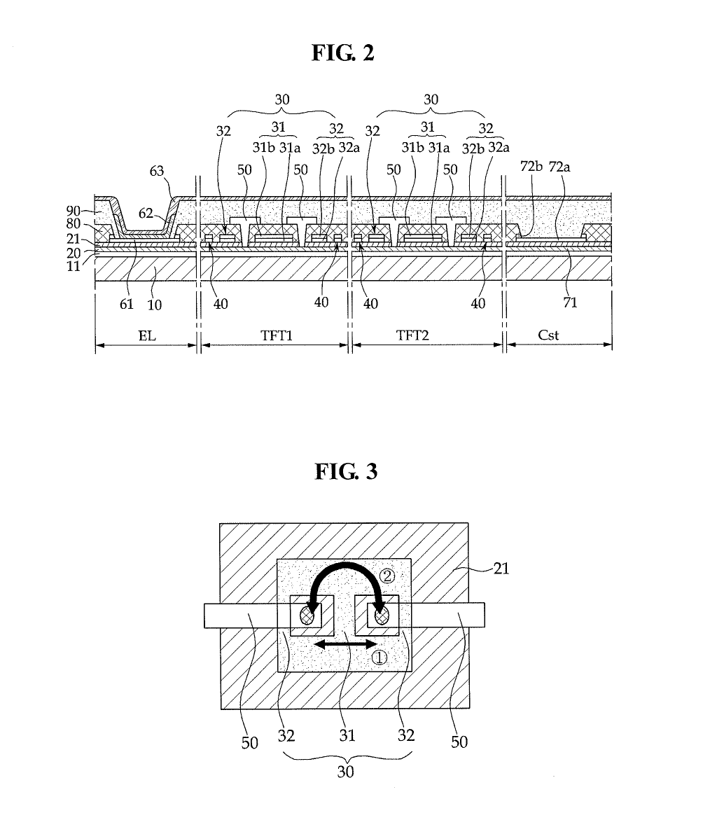

FIG. 2 illustrates, in cross-section, the organic light emitting element EL, the thin film transistors TFT1 and TFT2, and the storage capacitor Cst in FIG. 1. The two thin film transistors TFT1 and TFT2 have the same laminated structure.

The thin film transistors TFT1 and TFT2 include a substrate 10, a semiconductor layer 20 on the substrate 10, a first insulating layer 21 on the semiconductor layer 20, a gate electrode pattern 30 on the first insulating layer 21, a second insulating layer 80 on the gate electrode pattern 30, and a source electrode and a drain electrode 50 passing through the second insulating layer 80 and connected to the semiconductor layer 20.

The gate electrode pattern 30 includes a gate peripheral portion 32 having a closed-loop shape extending from a gate center portion 31. The source electrode and the drain electrode 50 are connected to the semiconductor layer 20 through an empty space at the center of the closed-loop shape.

The gate electrode pattern 30 may be divided into lower gate electrodes 31a and 32a and upper gate electrodes 31b and 32b. The lower gate electrodes 31a and 32a may be formed of a transparent conductive material.

The semiconductor layer 20 is not only formed in an area where the thin film transistors TFT1 and TFT2 are disposed, but also is uniformly formed on an entire area of the substrate 10, including an area where the organic light emitting element EL and the storage capacitor Cst are disposed.

In other words, the semiconductor layer 20 may be disposed on the entire surface of the substrate 10 without an additional patterning process. In this case, a mask process of patterning the semiconductor layer 20 may be omitted, so that the overall manufacturing process of the organic light emitting display may be simplified.

In some circumstances, the process of uniformly forming the semiconductor layer 20 on the entire surface of the substrate 10, instead of patterning the semiconductor layer 20, may lead to a short circuit caused by electrical non-separation between thin film transistors TFT1 and TFT2. In order to prevent this short-circuit phenomenon, a gate guard 40 is disposed at an area surrounding the gate electrode pattern 30. The gate guard 40 plays a role in providing electric separation between the thin film transistors TFT1 and TFT2.

The organic light emitting element EL includes a pixel electrode 61 and a facing electrode 63 that face each other. An emitting layer 62 is interposed between the pixel and facing electrodes 61 and 63. The pixel electrode 61 is made of a transparent conductive material and is connected to a drain electrode 50 of the driving transistor TFT2. Further, the pixel electrode 61 and the gate electrode pattern 30 of the thin film transistors TFT1 and TFT2 are formed simultaneously.

The storage capacitor Cst includes a lower electrode 71 and a upper electrode 72, with the first insulating layer 21 interposed therebetween. The upper electrode 72 of the storage capacitor Cst, the gate electrode pattern 30 of the thin film transistors TFT1 and TFT2, and the pixel electrode 61 of the organic light emitting element EL are formed simultaneously. Further, the upper electrode 72 of the storage capacitor Cst includes a second upper electrode 72b surrounding a first upper electrode 72a.

The lower electrode 71 uses part of an area of the semiconductor layer 20, instead of forming a separate layer. In other words, a storage capacitor Cst area of the semiconductor layer 20 is used as a lower electrode 71. In this case, electrical separation is required between the storage capacitor Cst and elements adjacent to the storage capacitor Cst. Thus, the second upper electrode 72b of the upper electrode 72 serves to provide an electrically separate structure.

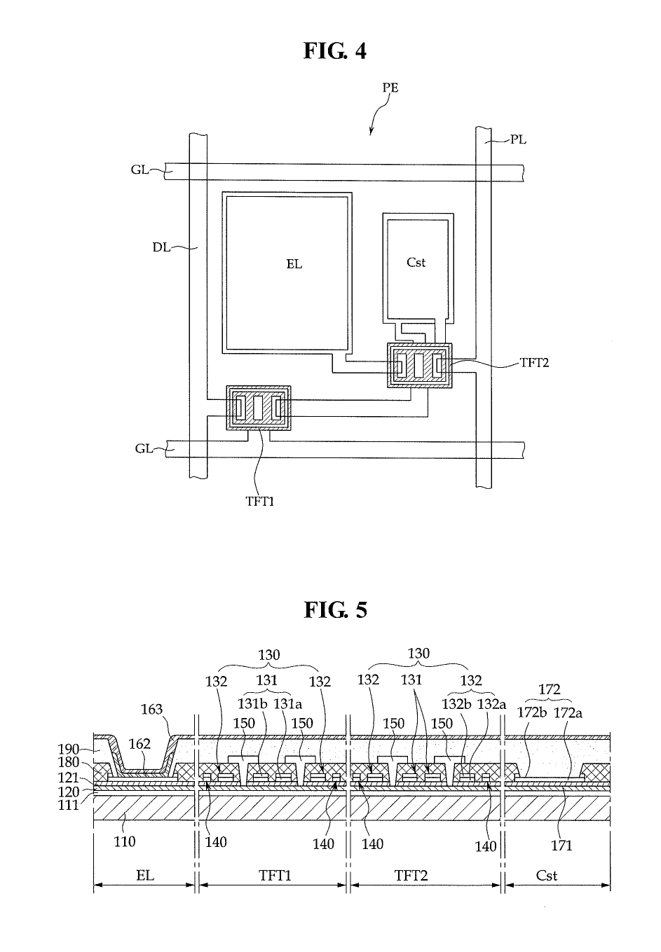

FIG. 3 illustrates one type of thin film transistor, which corresponds to either or both of the thin film transistors in FIG. 2. Referring to FIGS. 2 and 3, the thin film transistor includes a substrate 10, a semiconductor layer 20 on the substrate 10, a first insulating layer 21 on the semiconductor layer 20, a gate electrode pattern 30 on the first insulating layer 21, a second insulating layer 80 on the gate electrode pattern 30, a second insulating layer 80 on the gate electrode pattern 30, and a source electrode and a drain electrode 50 passing through the second insulating layer 80 and connected to the semiconductor layer 20.

The gate electrode pattern 30 includes a gate peripheral portion 32 having a closed-loop shape extending from a gate center portion. The source electrode and the drain electrode 50 are connected to the semiconductor layer 20 through an empty space at the center of the closed-loop.

In order to reduce the number of times a mask is used during manufacture, the thin film transistor is formed by coating the semiconductor layer on an entire surface of the substrate, instead of patterning the semiconductor layer. However, a greater amount of leakage current may be produced compared to the case where a patterning process is used for the semiconductor layer. That is, referring to FIG. 3, current flowing through the thin film transistor flows not only in a vertical direction \textcircled{1}, but also in a side direction \textcircled{2}. As a result, the total amount of leakage current in this transistor is large.

In accordance with one or more embodiments described herein, a display device and manufacturing method is provided in which a mask process for patterning a semiconductor layer is omitted. This may allow the thin film transistors to have optimized or predetermined properties.

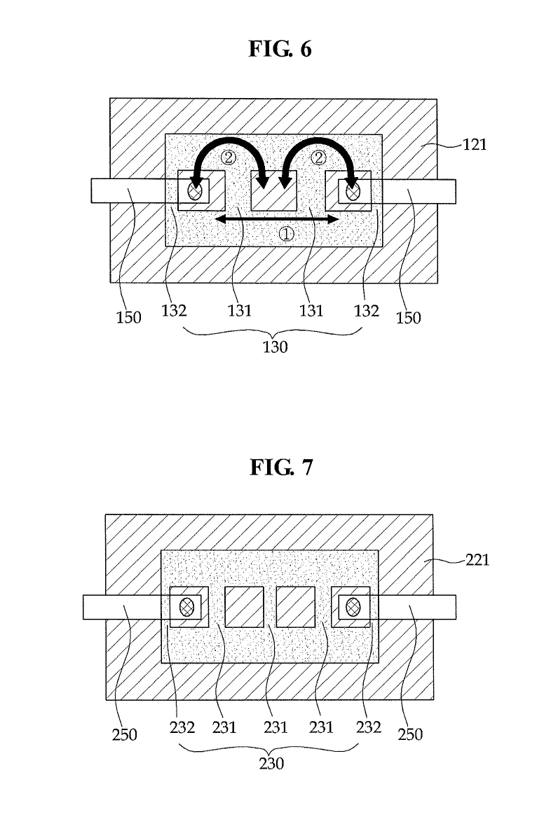

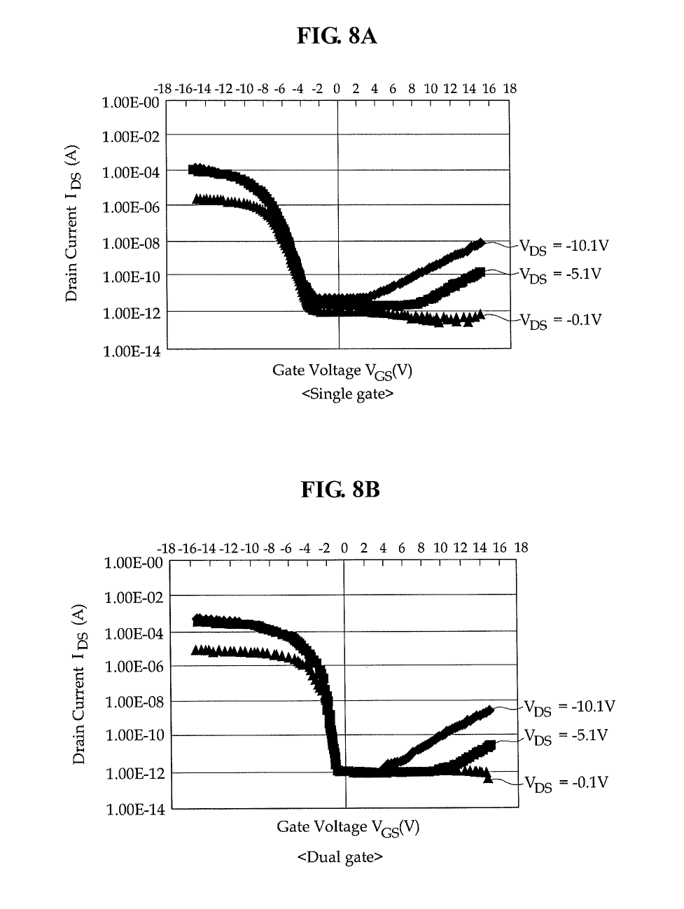

FIG. 4 illustrates an embodiment of a pixel of an organic light emitting display device, and FIG. 5 illustrates, in cross-section, example of an organic light emitting element EL, thin film transistors TFT1 and TFT2, and a storage capacitor Cst in FIG. 4.

Referring to FIGS. 4 and 5, the thin film transistors TFT1 and TFT2 include a substrate 110, a semiconductor layer 120 on the substrate 110, a first insulating layer 121 on the semiconductor layer 120, a gate electrode pattern 130 on the first insulating layer 121, a second insulating layer 180 on the gate electrode pattern 130, and a source electrode and a drain electrode 150 passing through the second insulating layer 180 and connected to the semiconductor layer 120.

The gate electrode pattern 130 includes a gate peripheral portion 132 having a closed-loop shape extending from a plurality of gate center portions 131. The source electrode and the drain electrode 150 are connected to the semiconductor layer 120 through empty spaces at the center of the closed-loop.

The gate electrode pattern 130 may be divided into lower gate electrodes 131a and 132a and upper gate electrodes 131b and 132b. The lower electrodes of the gate 131a and 132a may be formed of a transparent conductive material. In addition, a gate guard 140 may be disposed at an area surrounding the gate electrode pattern 130. The gate guard 140 may prevent a short circuit caused by electrical non-separation between thin film transistors TFT1 and TFT2.

The semiconductor 120 is not only formed in an area where the thin film transistors TFT1 and TFT2 are disposed, but also is uniformly formed on an entire area of the substrate 110 including an area where the organic light emitting element EL and the storage capacitor Cst are disposed. For example, a semiconductor layer 120 is disposed on the entire area of the substrate 110 without a separate patterning process.

The organic light emitting element EL includes a pixel electrode 161 and a facing electrode 163 that face each other, with a light emitting layer 162 therebetween. The pixel electrode 161 is made of a transparent conductive material connected to a drain electrode 150 of the driving transistor TFT2. Further, the pixel electrode 161 and the gate electrode pattern 130 of thin film transistors TFT1 and TFT2 may be formed simultaneously.

The storage capacitor Cst includes a lower electrode 171 and an upper electrode 172, with the first insulating layer 121 therebetween. The upper electrode 172 of the storage capacitor Cst, the gate electrode pattern 130 of the thin film transistors TFT1 and TFT2, and the pixel electrode 161 of the organic light emitting element EL may be simultaneously formed. Further, the upper electrode 172 of the storage capacitor Cst includes a first upper electrode 172a facing the lower electrode 171 and a second upper electrode 172b surrounding the first upper electrode 172a.

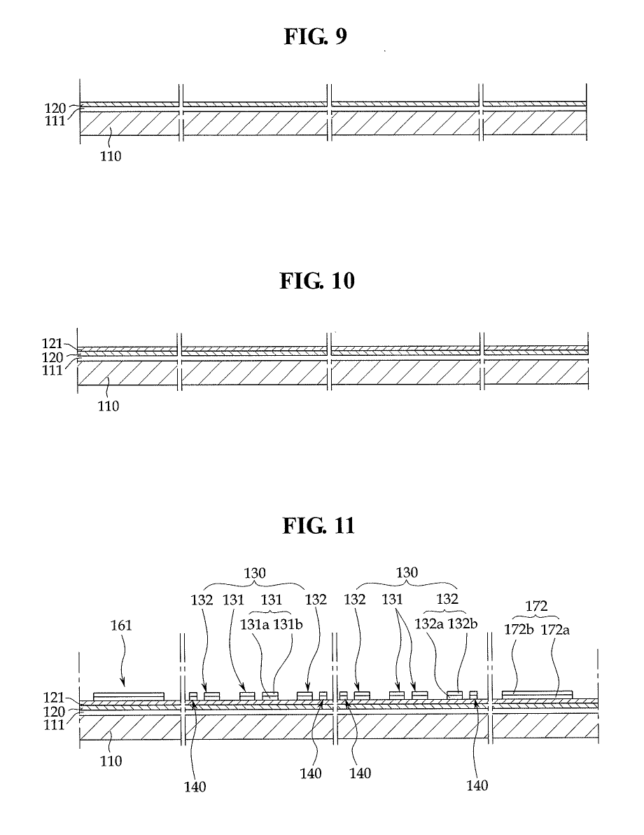

FIG. 6 illustrates an embodiment of a thin film transistor, which, for example, may correspond to either or both of the transistors in FIGS. 4 and 5. Referring to FIGS. 5 and 6, the thin film transistor includes a substrate 110, a semiconductor layer 120 on the substrate 110, a first insulating layer 121 on the semiconductor layer 120, a gate electrode pattern 130 on the first insulating layer 121, a second insulating layer 180 on the gate electrode pattern 130, and a source electrode and a drain electrode 150 passing through the second insulating layer 180 and connected to the semiconductor layer 120.

The gate electrode pattern 130 includes two gate center portions 131, and a gate peripheral portion 132 having a closed-loop shape extending from the gate center portions 131. The source electrode and the drain electrode 150 are connected to the semiconductor layer 120 through empty spaces at the center of the closed-loop.

Thus, in this embodiment, two gate center portions are included which perform like gate electrodes, thereby effectively operating as a kind of double-gate structure. As a result, the leakage current flowing in the side direction \textcircled{2} in FIG. 3 can be reduced or prevented in this embodiment.

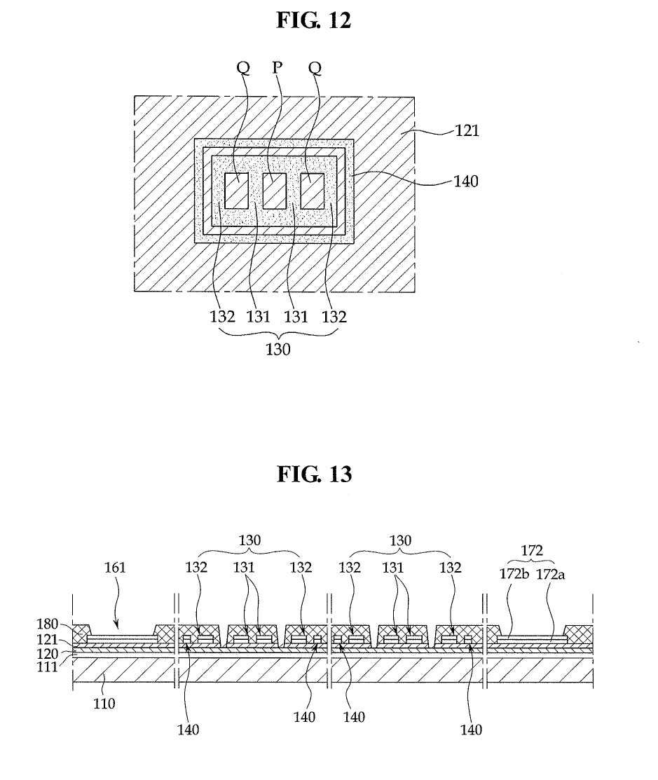

FIG. 7 illustrates another embodiment of a thin film transistor, which, for example, may correspond to either or both of the transistors in FIGS. 4 and 5. Referring to FIG. 7, the thin film transistor includes a substrate, a semiconductor layer on the substrate, a first insulating layer 221 on the semiconductor layer, a gate electrode pattern 230 on the first insulating layer 221, a second insulating layer on the gate electrode pattern 230, and a source electrode and a drain electrode 250 passing through the second insulating layer 280 and connected to the semiconductor layer.

The gate electrode pattern 230 includes three gate center portions 231, and a gate peripheral portion 232 having a closed-loop shape extending from the gate center portions 231. The source electrode and the drain electrode 250 are connected to the semiconductor layer through empty spaces at the center of the closed-loop. In this embodiment, the three gate center portions perform like gate electrodes, thereby effectively producing a kind of triple-gate structure. As a result, leakage current flowing in the side direction may be reduced or prevented.

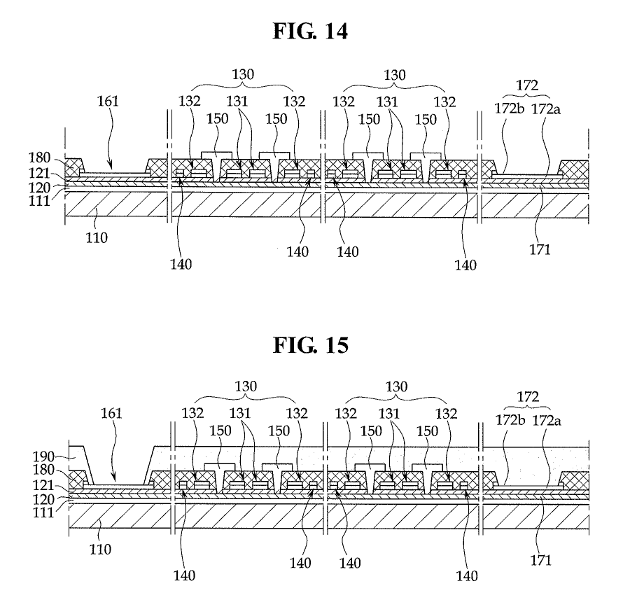

FIG. 8A is a graph representing leakage current of a single-gate thin film transistor (e.g., as shown in FIGS. 2 and 3), and FIG. 8B illustrates a graph representing leakage current of a multiple-gate thin film transistor according to one or more of the aforementioned embodiments. When comparing FIGS. 8A and 8B, the leakage current of the thin film transistor according to one or more of the aforementioned embodiments is below the leakage current of the thin film transistor in FIGS. 2 and 3.

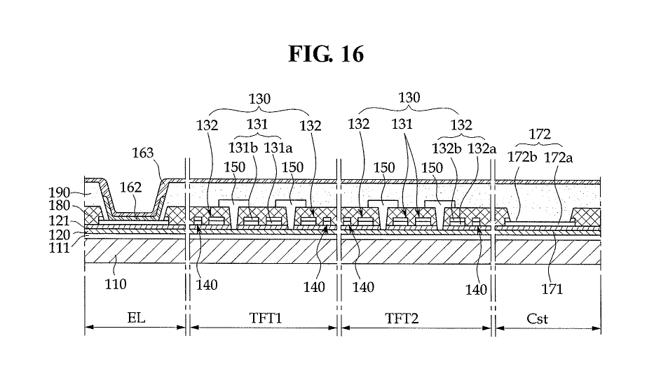

FIGS. 9 through 16 illustrate operations included in one embodiment of a method for manufacturing an organic light emitting display device. Referring to FIG. 9, an initial operation includes forming a buffer layer 111 on the substrate 110 for planarizing the substrate 110 and preventing impurity penetration, and forming the semiconductor layer 120 uniformly thereon. The substrate 110 may be made, for example, of transparent glass material. The semiconductor layer 120 may be made, for example, of a polycrystalline silicon material.

Next, as illustrated in FIG. 10, the first insulating layer 121 is formed on the semiconductor layer 120 without an additional mask patterning process. Thus, a mask process for patterning semiconductor layer may be omitted compared to other methods. However, because the patterning process of the semiconductor layer is omitted, electrical non-separation may result. This will be addressed in subsequent operations. The first insulating layer 121 may be formed, for example, by depositing an inorganic insulating layer such as SiNx or SiOx using, for example, a plasma enhanced chemical vapor deposition (PECVD) method, an atmospheric pressure chemical vapor deposition (APCVD) method, or a low pressure chemical vapor deposition (LPCVD) method.

Next, as illustrated in FIG. 11, the pixel electrode 161 of the organic light emitting element EL, a gate electrode pattern 130 of the thin film transistors TFT1 and TFT2, and the upper electrode 172 of the storage capacitor Cst are formed on the upper portion of the first insulating layer 121. Thus, two conductive layers are sequentially formed on the first insulating layer 121, and then a pattern of the pixel electrode 161, the gate electrode pattern 130, and the upper electrode 172 are formed by a mask process using a first mask.

One of the two conductive layers first formed at the bottom may include at least one transparent material selected, for example, from a group consisting of ITO, IZO, ZnO, and In₂O₃. This transparent material layer later becomes a pixel electrode 161, lower electrodes of the gate 131a and 132a, and the first upper electrode 172a of the storage capacitor Cst.

Further, one of the two conductive layers formed at the top may include at least one metallic material selected, for example, from a group consisting of Ag, Mg, Al, Pt, Pd, Au, Ni, Nd, Ir, Cr, Li, Ca, Mo, Ti, W, MoW, and Al/Cu. This metal material layer is later patterned and becomes upper electrodes of the gate 131b and 132b, and the second upper electrode 172b of the storage capacitor Cst.

Further, the gate guard 140 is patterned together with the same material on the same layer. The gate guard 140 surrounds the gate electrode pattern 130, and plays a role in causing electrical separation between adjacent elements of the semiconductor layer 120 in a subsequent doping process.

FIG. 12 illustrates an example of the gate electrode pattern 130 and a pattern of the gate guard 140. As illustrated in FIG. 12, the gate guard 140 surrounds the gate electrode pattern 130 and provides a space separate from adjacent elements. Further, as previously indicated, the gate electrode pattern 130 includes the two gate center portions 131 and the gate peripheral portion 132. Empty spaces are formed between the gate center portions 131 and the gate peripheral portion 132.

Next, n-type or p-type impurity doping is performed from the upper portion of the drawing. In this case, impurities do not pass through a portion covered by the metal material layer, but passes through a portion not covered by the metal material layer, to allow the semiconductor layer 120 to be doped with impurities.

Accordingly, as illustrated in FIG. 12, an area P between the gate center portions 131 and areas Q between the gate center portions 131 and the gate peripheral portion 132 are doped with impurities. In a later process, the source electrode and the drain electrode 150 are connected to the semiconductor layer 120 through respective Q areas.

Further, because the gate guard 140 covered with the metal material layer is formed at the outer boundary region of the gate electrode pattern 130, the semiconductor layer 120 below the gate guard 140 may not be doped, and therefore may be electrically separated from adjacent elements. For example, impurity doping is performed using the gate electrode pattern 130 and the gate guard 140 as masks.

Meanwhile, the pixel electrode 161 of the organic light emitting element EL and the upper electrode 172 of the storage capacitor Cst are still covered with the metal material layer. Thus, the semiconductor layer 120 below the metal material layer are not doped with impurities.

Next, as illustrated in FIG. 13, the second insulating layer 180 is deposited on the entire surface of the substrate 110. Openings having predetermined patterns are formed by a mask process using a second mask. These openings expose the pixel electrode 161 of the organic light emitting element EL and the upper electrode 172 of the storage capacitor Cst. Further, the semiconductor layer 120 is exposed through the first insulating layer 121 and the second insulating layer 180 in the area Q between the gate center portions 131 and the peripheral portion 132.

The second insulating layer 180 may be formed by a spin coating method using at least one organic insulating material selected, for example, from a group consisting of polyimide, polyamide, acryl resin, benzocyclobutene, and phenol resin.

Next, as illustrated in FIG. 14, a conductive layer is deposited on the entire surface of the substrate 110. Then, the source electrode and the drain electrode 150 are formed by a mask process using a third mask. In this case, the conductive layer may be formed as a metal material layer. The conductive layer may be deposited with a thickness sufficient to fill the openings, and then may be removed except for the source electrode and the drain electrode 150 by the mask process.

The pixel electrode 161 of the organic light emitting element EL and the metal material layer at the upper electrode 172 of the storage capacitor Cst are removed by performing etching. However, side edges of the pixel electrode 161 and the upper electrode 172 are buried in the second insulating layer 180, and therefore remain after the etching process. The residual side edges of the second upper electrode 172b of the storage capacitor Cst perform like a mask similar to the gate guard 140 of the gate electrode pattern 130.

For example, after the source electrode and the drain electrode 150 are formed, the doping process is performed to form the lower electrode 171 of the storage capacitor Cst. In this case, as illustrated in FIG. 13, the residual second upper electrode 172b surrounds the first upper electrode 172a. Thus, the semiconductor layer 120 below the residual second upper electrode 172b may not be doped. Accordingly, a part of the semiconductor layer 120 facing the first upper electrode 172a is doped and the lower electrode 171 is formed. However, a part of the semiconductor layer 120 below the second upper electrode 172b is not doped, such that a boundary line which electrically separates the semiconductor layer 120 from adjacent elements may be formed.

Accordingly, although the semiconductor layer 120 is not patterned using a separate mask, it is possible to provide both of the semiconductor layer 120 and the lower electrode 171 required for the thin film transistors TFT1 and TFT2 and the storage capacitor Cst in electrically separated structures.

Next, as illustrated in FIG. 15, a pixel define layer (PDL) 190 is formed on the substrate 110. The pixel define layer 190 may be formed of at least one organic insulating material selected, for example, from a group consisting of polyimide, polyamide, acryl resin, benzocyclobutene, and phenol resin. Openings for exposing a center portion of the pixel electrode 161 may be formed by a mask process using a fourth mask. Next, as illustrated in FIG. 16, a light emitting layer 162 and the facing electrode 163 are formed on the pixel electrode 161.

By way of summation and review, in one type of active matrix display, each pixel includes an organic light emitting diode formed on a substrate, which is patterned to include a thin film transistor, a capacitor, and associated wirings. In order to form a micro pattern including the thin film transistor on the substrate, the pattern is transferred to an array substrate using a mask having the micro pattern formed thereon. The pattern transfer process using the mask may be performed by a photo-lithograph process.

In a photo-lithography process, a photoresist may be uniformly coated on a substrate on which the pattern is to be formed. The photoresist is then exposed using an exposing device such as a stepper, and then (in a case of a positive photoresist) the sensitized photoresist is subjected to a developing process. After the photoresist is developed, the pattern is etched using the residual photoresist as a mask. Then, an unnecessary portion of the photoresist is removed.

In the aforementioned process of transferring a pattern using a mask, a mask having a desired pattern is required to be prepared in advance. Therefore, as the number of processes that involve the mask increases, manufacturing costs may also increase.

In accordance with one or more embodiments, a method for manufacturing a display device omits a process of patterning a semiconductor layer using a mask, to thereby achieve predetermined or optimized properties of thin film transistors.

Example embodiments have been disclosed herein, and although specific terms are employed, they are used and are to be interpreted in a generic and descriptive sense only and not for purpose of limitation. In some instances, as would be apparent to one of skill in the art as of the filing of the present application, features, characteristics, and/or elements described in connection with a particular embodiment may be used singly or in combination with features, characteristics, and/or elements described in connection with other embodiments unless otherwise indicated. Accordingly, it will be understood by those of skill in the art that various changes in form and details may be made without departing from the spirit and scope of the present invention as set forth in the following claims.

What is claimed is:

1. A display device, comprising:
a substrate;
a thin film transistor including a semiconductor layer on the substrate; and
an organic light emitting element and a capacitor electrically connected to the thin film transistor, wherein the semiconductor layer is uniformly disposed on an entire area of the substrate, and wherein the thin film transistor includes:
a first insulating layer on the semiconductor layer;
a gate electrode pattern on the first insulating layer and including a plurality of gate center portions and a gate peripheral portion having a closed-loop shape extending from the gate center portions;
a gate guard on a same layer as and surrounding the gate electrode pattern;
a second insulating layer on the gate electrode pattern and the gate guard; and
a source electrode and a drain electrode passing through the first insulating layer and the second insulating layer and connected to the semiconductor layer.

2. The display device as claimed in claim 1, wherein the gate guard includes a same material as the gate electrode pattern.

3. The display device as claimed in claim 1, wherein the source electrode and the drain electrode are connected to the semiconductor layer through empty spaces of the closed loop formed by the gate center portions and the gate peripheral portions.

4. A method of manufacturing a display device, the method comprising:
uniformly forming a semiconductor layer on an entire area of a substrate which includes an organic light emitting element, a thin film transistor, and a capacitor;
forming a first insulating layer on the semiconductor layer;
performing a first mask process which includes patterning a conductive layer on the first insulating layer to form a gate electrode pattern having a plurality of gate center portions and a gate peripheral portion in a closed-loop shape extending from the gate center portions, a gate guard surrounding the gate electrode pattern, and a pixel electrode of the organic light emitting element and an upper electrode of the capacitor;
performing a second mask process which includes patterning a second insulating layer to expose the pixel electrode, the upper electrode, and the semiconductor layer of the thin film transistor;
performing a third mask process which includes patterning a conductive layer to form a source electrode and a drain electrode which contact an exposed portion of the semiconductor layer; and
performing a fourth mask process which includes patterning a pixel-define-layer forming material layer to expose the pixel electrode.

5. The method as claimed in claim 4, wherein the gate guard is formed on the same layer as the gate electrode pattern and surrounds the gate electrode pattern.

6. The method as claimed in claim 5, wherein the gate guard includes a same material as the gate electrode pattern.

7. The method as claimed in claim 5, the method further comprising:
doping the semiconductor layer with impurities using the gate electrode pattern and the gate guard as masks.

8. The method as claimed in claim 5, wherein the thin film transistor area exposing the semiconductor layer includes empty spaces of a closed loop formed by the gate center portions and the gate peripheral portion.

9. A transistor, comprising:
a drain electrode;
a source electrode;
a semiconductor layer; and
a multiple gate structure including an insulating material between a first gate area and a second gate area, wherein the drain and source electrodes are electrically connected to the semiconductor layer and wherein the semiconductor layer overlaps the first gate area and the second gate area.

10. The transistor as claimed in claim 9, further comprising:
a gate region adjacent the first and second gate areas.

11. The transistor as claimed in claim 10, wherein the gate region surrounds the first and second gate areas, and wherein the drain and source electrodes overlap the gate region.

12. The transistor as claimed in claim 9, wherein the first and second gate areas block leakage current in a predetermined direction.

13. The transistor as claimed in claim 9, wherein the multiple gate structure includes a third gate area between the first and second gate areas, and wherein the insulating material extends between the first and third gate areas and between the second and third gate areas.

14. The transistor as claimed in claim 9, wherein the semiconductor layer is continuously disposed on a substrate to overlap the transistor and at least one of additional transistor, a capacitor, or a light emitting layer.

15. The transistor as claimed in claim 14, wherein the semiconductor layer is continuously disposed on a substrate to overlap the transistor, additional transistor, a capacitor, and a light emitting layer.

16. The transistor as claimed in claim 9, wherein the semiconductor layer is an unpatterned layer.

17. The transistor as claimed in claim 9, further comprising:
a gate guard adjacent the multiple gate structure.

18. A pixel, comprising:
a capacitor;
a light emitting layer; and
a transistor between the capacitor and light emitting layer, and including:
a drain electrode;
a source electrode;
a semiconductor layer; and
a multiple gate structure including an insulating material between a first gate area and a second gate area, wherein the drain and source electrodes are electrically connected to the semiconductor layer and wherein the semiconductor layer overlaps the first gate area and the second gate area.

19. The pixel as claimed in claim 18, wherein the semiconductor layer is continuously disposed on a substrate to overlap the capacitor and light emitting layer.

20. The pixel as claimed in claim 18, further comprising:
a gate region which surrounds the first and second gate areas,
wherein the drain and source electrodes overlap the gate region.
